(19) United States
(12) Patent Application Publication
(10) Pub. No.: US 2025/0311086 A1
(43) Pub. Date: Oct. 2, 2025

(54) PRINTED CIRCUIT BOARD AND ELECTRONIC CONTROL DEVICE

(71) Applicant: DENSO CORPORATION, Kariya-city (JP)

(72) Inventors: Masato IMAMURA, Kariya-city (JP); Tetsuya OISHI, Kariya-city (JP)

(21) Appl. No.: 19/075,917

(22) Filed: Mar. 11, 2025

(30) Foreign Application Priority Data
Mar. 27, 2024 (JP) 2024-051449

(51) Int. Cl. H05K 1/02; H05K 1/11

(52) U.S. Cl. CPC H05K 1/0206; H05K 1/115; H05K 2201/09518; H05K 2201/09545; H05K 2201/09618; H05K 2201/09627; H05K 2201/10015; H05K 2201/10212; H05K 2201/10462

(57) ABSTRACT

A printed circuit board includes a plurality of dielectric layers, a plurality of conductive pattern layers, a first through hole, a second through hole, and an inner layer via. The inner layer via penetrates through each dielectric layer from an Mth dielectric layer to the (N-1)th dielectric layer, where M is an integer that is greater than equal to two and less than or equal to (N-1) and has an inner circumferential surface on which an inner layer via conductor is disposed. At least a portion of the inner layer via is disposed in an inner via arrangement region. At least one of the first through hole and the second through hole is connected to the inner layer via with at least one conductive pattern layer that is selected from a second conductive pattern layer to an Nth conductive pattern layer in the plurality of conductive pattern layers.

### CROSS REFERENCE TO RELATED APPLICATION

The present application claims the benefit of priority from Japanese Patent Application No. 2024-051449 filed on Mar. 27, 2024. The entire disclosure of the above application is incorporated herein by reference.

### TECHNICAL FIELD

The present disclosure relates to a printed circuit board and an electronic control device.

### BACKGROUND

When connecting a printed circuit board and terminals of an electronic component by soldering, heat generated during soldering is not easily transferred to a rear surface, which may result in poor solderability. If the solderability is poor, thermal stress can result in cracks in the solder. When these cracks gradually increase, the electrical connection can eventually be lost, leading to failure.

### SUMMARY

The present disclosure provides a printed circuit board. According to one example, the printed circuit board includes a plurality of dielectric layers from a first dielectric layer to an (N-1)th dielectric layer, where N is an integer that is greater than or equal to three, a plurality of conductive pattern layers from a first conductive pattern layer to an Nth conductive pattern layer, a first through hole, a second through hole, and an inner layer via.

The plurality of conductive pattern layers are laminated alternately with the plurality of dielectric layers in such a manner that that the first conductive pattern layer is disposed above the first dielectric layer and the (N-1)th dielectric layer is disposed above the Nth conductive pattern layer. The first through hole penetrates through the plurality of dielectric layers from the first dielectric layer to the (N-1)th dielectric layer, and has an inner circumferential surface on which a first through hole conductor is disposed. A positive electrode terminal of a capacitor is to be inserted into the first through hole in a state where the capacitor is mounted above the first conductive pattern layer.

The second through hole penetrates through the plurality of dielectric layers from the first dielectric layer to the (N-1)th dielectric layer, and has an inner circumferential surface on which a second through hole conductor is disposed. A negative electrode terminal of the capacitor is to be inserted into the second through hole in the state where the capacitor is mounted above the first conductive pattern layer.

The inner layer via penetrates through each dielectric layer from an Mth dielectric layer to the (N-1)th dielectric layer in the plurality of dielectric layers, where M is an integer that is greater than or equal to two and less than or equal to (N-1), and has an inner circumferential surface on which an inner layer via conductor is disposed. At least a portion of the inner layer via is disposed in an inner via arrangement region. The inner via arrangement region is a region that is located just under the capacitor in the state where the capacitor is mounted above the first conductive pattern layer, and the positive electrode terminal and the negative electrode terminal of the capacitor are inserted into the first through hole and the second through hole, respectively, and the inner via arrangement region is sandwiched between a first straight line and a second straight line.

The first straight line and the second straight line are arranged parallel to each other and separated from each other by a through hole distance that is a distance between the first through hole and the second through hole, the first straight line and the second straight line intersect perpendicularly a through hole connecting straight line that connects a center of the first through hole and a center of the second through hole, and the first straight line and the second straight line are arranged between the first through hole and the second through hole.

At least one of the first through hole and the second through hole is connected to the inner layer via with at least one conductive pattern layer that is selected from an Mth conductive pattern layer to the Nth conductive pattern layer in the plurality of conductive pattern layers.

The present disclosure also provides an electronic control device including a capacitor and the above-described printed circuit board on which the capacitor is mounted.

### BRIEF DESCRIPTION OF DRAWINGS

Objects, features and advantages of the present disclosure will become apparent from the following detailed description made with reference to the accompanying drawings. In the drawings:

FIG. 1 is a block diagram showing a configuration of an electronic control device;

FIG. 2 is a cross-sectional view showing a configuration of a printed circuit board according to a first embodiment;

FIG. 3 is a diagram showing a shape of a conductive pattern layer on a mounting surface;

FIG. 4 is a diagram showing a shape of a conductive pattern layer on a dielectric layer inside the printed circuit board;

FIG. 5 is a diagram showing a shape of a conductive pattern layer on a soldering surface; and

FIG. 6 is a cross-sectional view showing a configuration of a printed circuit board according to a second embodiment.

### DETAILED DESCRIPTION

In a printed circuit board, a plurality of vias may be arranged around through holes into which terminals of an electronic component are inserted so that heat generated during soldering can be efficiently transferred to a rear surface.

However, in the printed circuit board described above, when a capacitor is mounted on the printed circuit board, a distance between a wiring pattern having the same potential as a positive electrode terminal of the capacitor and a wiring pattern having the same potential as a negative electrode terminal of the capacitor may be shorter than a distance between the positive electrode terminal and the negative electrode terminal of the capacitor. In such a configuration, if electrolyte leaks from the capacitor mounted on the printed circuit board, the electrolyte may spread onto the wiring patterns, causing migration and resulting in a short circuit of the capacitor.

A printed circuit board according to a first aspect of the present disclosure includes a plurality of dielectric layers from a first dielectric layer to an (N-1)th dielectric layer, where N is an integer that is greater than or equal to three, a plurality of conductive pattern layers from a first conductive pattern layer to an Nth conductive pattern layer, a first through hole, a second through hole, and an inner layer via.

The plurality of conductive pattern layers are laminated alternately with the plurality of dielectric layers in such a manner that that the first conductive pattern layer is disposed above the first dielectric layer and the (N-1)th dielectric layer is disposed above the Nth conductive pattern layer. The first through hole penetrates through the plurality of dielectric layers from the first dielectric layer to the (N-1)th dielectric layer, and has an inner circumferential surface on which a first through hole conductor is disposed. A positive electrode terminal of a capacitor is to be inserted into the first through hole in a state where the capacitor is mounted above the first conductive pattern layer.

The second through hole penetrates through the plurality of dielectric layers from the first dielectric layer to the (N-1)th dielectric layer, and has an inner circumferential surface on which a second through hole conductor is disposed. A negative electrode terminal of the capacitor is to be inserted in the second through hole in the state where the capacitor is mounted above the first conductive pattern layer.

The inner layer via penetrates through each dielectric layer from an Mth dielectric layer to the (N-1)th dielectric layer in the plurality of dielectric layers, where M is an integer that is greater than or equal to two and less than or equal to (N-1), and has an inner circumferential surface on which an inner layer via conductor is disposed. At least a portion of the inner layer via is disposed in an inner via arrangement region. The inner via arrangement region is a region that is located just under the capacitor in the state where the capacitor is mounted above the first conductive pattern layer, and the positive electrode terminal and the negative electrode terminal of the capacitor are inserted into the first through hole and the second through hole, respectively. The inner via arrangement region is sandwiched between a first straight line and a second straight line.

The first straight line and the second straight line are arranged parallel to each other and separated from each other by a through hole distance that is a distance between the first through hole and the second through hole. The first straight line and the second straight line intersect perpendicularly a through hole connecting straight line that connects a center of the first through hole and a center of the second through hole. The first straight line and the second straight line are arranged between the first through hole and the second through hole.

At least one of the first through hole and the second through hole is connected to the inner layer via with at least one conductive pattern layer that is selected from an Mth conductive pattern layer to the Nth conductive pattern layer in the plurality of conductive pattern layers.

The printed circuit board of the first aspect configured in this manner has the inner layer via connected to at least one of the first through hole and the second through hole, thereby increasing the number of paths for conducting heat between the first conductive pattern layer and the Nth conductive pattern layer, and making it easier to conduct heat between the first conductive pattern layer and the Nth conductive pattern layer. This makes it easier for heat generated during soldering to be conducted through the first through hole and the second through hole from portions adjacent to the first conductive pattern layer to portions adjacent to the Nth conductive pattern layer. Therefore, the printed circuit board of the first aspect can restrict deterioration of solderability when soldering the positive electrode terminal and the negative electrode terminal of the capacitor into the first through hole and the second through hole, respectively.

Furthermore, in the printed circuit board of the first aspect, the inner layer via disposed in the inner layer via arrangement region is not exposed on the mounting surface of the printed circuit board on which the capacitor is to be mounted. Accordingly, the printed circuit board of the first aspect can restrict the occurrence of a situation in which the capacitor shorts out between the first through hole and the second through hole when electrolyte leaks from the capacitor mounted on the printed circuit board.

As described above, the printed circuit board according to the first aspect of the present disclosure can improve the reliability of the printed circuit board.

An electronic control device according to a second aspect of the present disclosure includes a capacitor and a printed circuit board on which the capacitor is mounted.

The printed circuit board includes a plurality of dielectric layers from a first dielectric layer to an (N-1)th dielectric layer, a plurality of conductive pattern layers from a first conductive pattern layer to an Nth conductive pattern layer, a first through hole, a second through hole, and an inner layer via. At least one of the first through hole and the second through hole is connected to the inner layer via with at least one conductive pattern layer that is selected from a second conductive pattern layer to the Nth conductive pattern layer in the plurality of conductive pattern layers.

The electronic control device of the second aspect configured as described above includes the printed circuit board according to the first aspect, and can obtain the same effects as the printed circuit board of the first aspect.

### First Embodiment

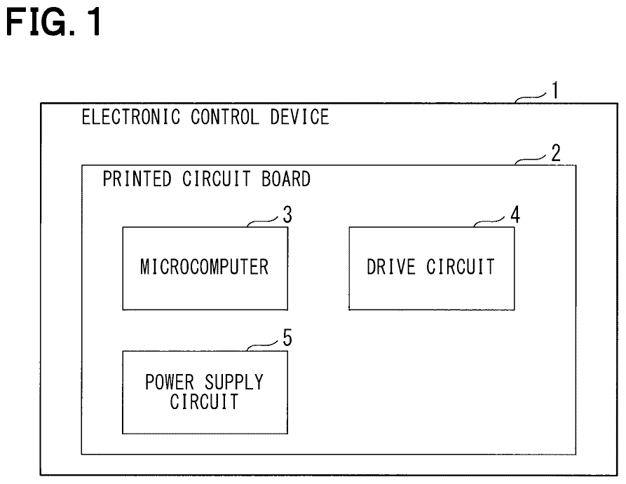

Hereinafter, a first embodiment according to the present disclosure will be described with reference to the drawings. An electronic control device 1 of the present embodiment is a device that controls a controlled object (not shown), and includes a printed circuit board 2 as shown in FIG. 1. The electronic control device 1 is configured by housing the printed circuit board 2 in a housing (not shown).

On the printed circuit board 2, a microcomputer 3, a drive circuit 4 and a power supply circuit 5 are mounted. The microcomputer 3 executes various control processes for controlling the controlled object, and outputs a control signal indicating a control amount for controlling the controlled object to the drive circuit 4.

Based on the control signal from the microcomputer 3, the drive circuit 4 outputs a drive signal for driving the controlled object to the controlled object. The power supply circuit 5 is a circuit that generates a predetermined power supply voltage for operating the microcomputer 3 and the drive circuit 4.

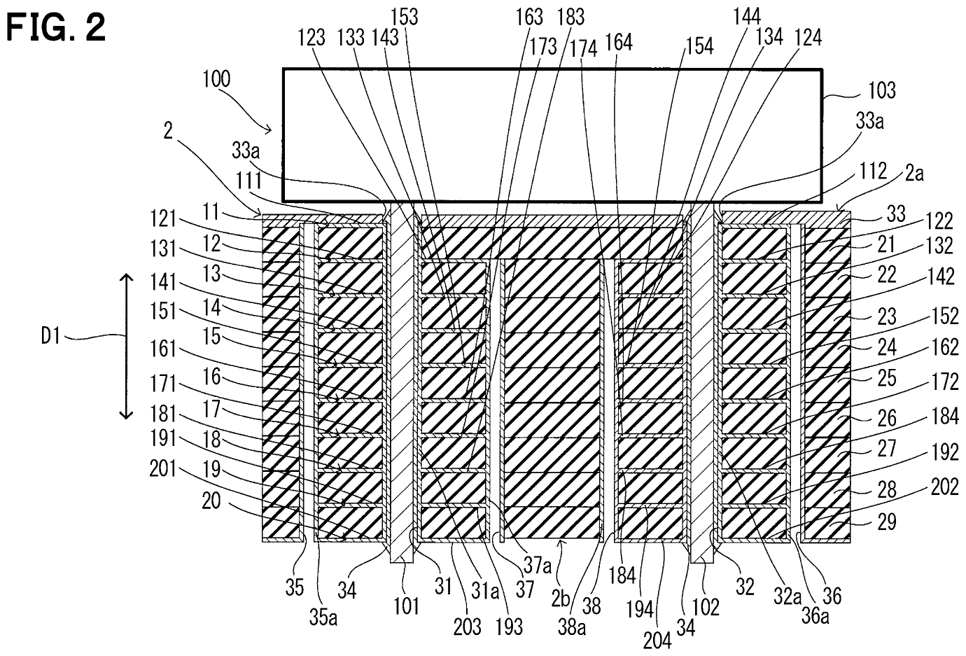

As shown in FIG. 2, the printed circuit board 2 includes ten conductive pattern layers 11, 12, 13, 14, 15, 16, 17, 18, 19, and 20, and nine dielectric layers 21, 22, 23, 24, 25, 26, 27, 28, and 29. The printed circuit board 2 is formed by laminating the ten conductive pattern layers 11 to 20 and the nine dielectric layers 21 to 29 alternately along a laminating direction D1.

Therefore, the conductive pattern layer 11 is disposed above the dielectric layer 21. The conductive pattern layer 12 is disposed between the dielectric layer 21 and the dielectric layer 22. The conductive pattern layer 13 is disposed between the dielectric layer 22 and the dielectric layer 23. The conductive pattern layer 14 is disposed between the dielectric layer 23 and the dielectric layer 24. The conductive pattern layer 15 is disposed between the dielectric layer 24 and the dielectric layer 25. The conductive pattern layer 16 is disposed between the dielectric layer 25 and the dielectric layer 26. The conductive pattern layer 17 is disposed between the dielectric layer 26 and the dielectric layer 27. The conductive pattern layer 18 is disposed between the dielectric layer 27 and the dielectric layer 28. The conductive pattern layer 19 is disposed between the dielectric layer 28 and the dielectric layer 29. The dielectric layer 29 is disposed above the conductive pattern layer 20.

The printed circuit board 2 is formed with a positive electrode terminal through hole 31 into which a positive electrode terminal 101 of a capacitor 100 is to be inserted, and a negative electrode terminal through hole 32 into which a negative electrode terminal 102 of the capacitor 100 is to be inserted. The capacitor 100 is, for example, a component of the power supply circuit 5. In the present embodiment, the capacitor 100 is an aluminum electrolytic capacitor.

The positive electrode terminal through hole 31 and the negative electrode terminal through hole 32 are formed so as to penetrate through the dielectric layers 21 to 29. A conductor 31a is formed over the entire inner circumferential surface of the positive electrode terminal through hole 31. In addition, a conductor 32a is formed over the entire inner circumferential surface of the negative electrode terminal through hole 32. Hereinafter, the conductor 31a and the conductor 32a will be referred to as a positive electrode terminal through hole conductor 31a and a negative electrode terminal through hole conductor 32a, respectively.

The printed circuit board 2 includes a solder resist 33. The solder resist 33 is disposed on the conductive pattern layer 11 and on a region of the dielectric layer 21 where the conductive pattern layer 11 is not disposed. However, the solder resist 33 is arranged so as not to cover openings of the positive electrode terminal through hole 31 and the negative electrode terminal through hole 32. As a result, resist openings 33a are formed so that the openings of the positive electrode terminal through hole 31 and the negative electrode terminal through hole 32 are exposed.

The positive electrode terminal 101 and the negative electrode terminal 102 of the capacitor 100 are conductors each formed in a linear shape. The positive electrode terminal 101 and the negative electrode terminal 102 are inserted into the positive electrode terminal through hole 31 and the negative electrode terminal through hole 32 from the resist openings 33a, respectively. End portions of the positive electrode terminal 101 and the negative electrode terminal 102 protrude from the openings of the positive electrode terminal through hole 31 and the negative electrode terminal through hole 32 on a surface of the printed circuit board 2 opposite to a surface on which the resist openings 33a are formed.

Of the two surfaces of the printed circuit board 2 formed in a plate shape, the surface on which a body portion 103 of the capacitor 100 is disposed is hereinafter referred to as a mounting surface 2a. Of the two surfaces of the printed circuit board 2, the surface from which the end portions of the positive electrode terminal 101 and the negative electrode terminal 102 of the capacitor 100 protrude is referred to as a soldering surface 2b.

With the positive electrode terminal 101 and the negative electrode terminal 102 of the capacitor 100 inserted into the positive electrode terminal through hole 31 and the negative electrode terminal through hole 32, respectively, the capacitor 100 is fixed to the printed circuit board 2 by filling a space between the positive electrode terminal 101 and the positive electrode terminal through hole 31, and a space between the negative electrode terminal 102 and the negative electrode terminal through hole 32 with a solder 34.

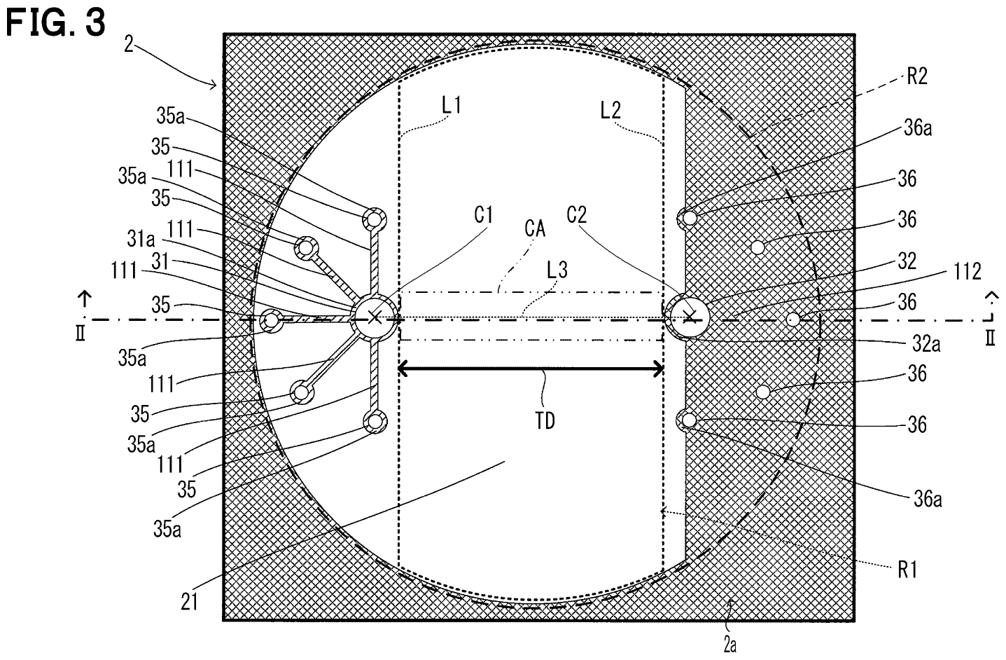

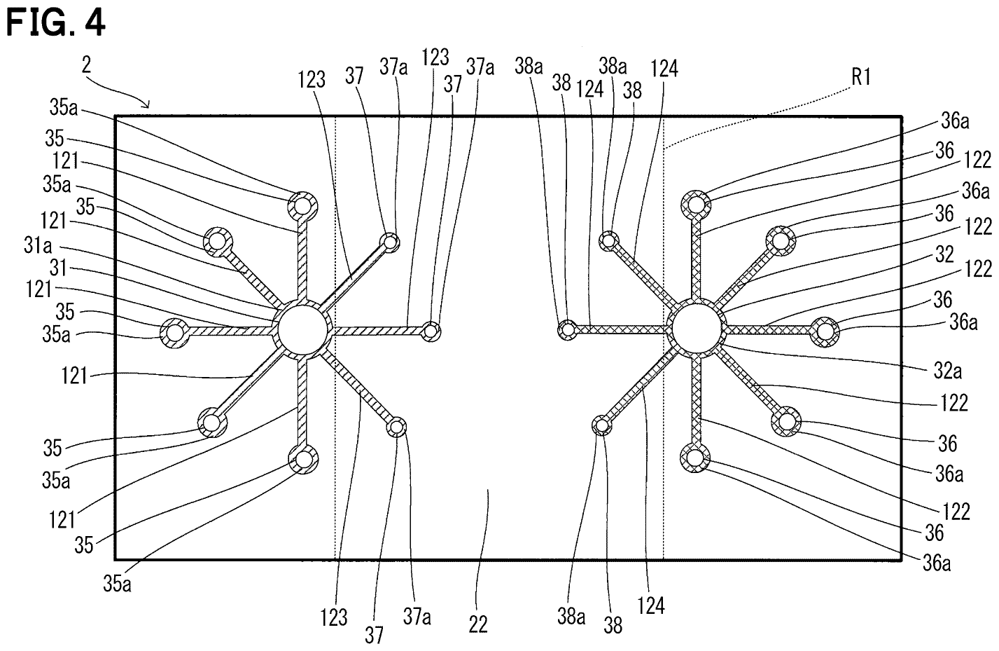

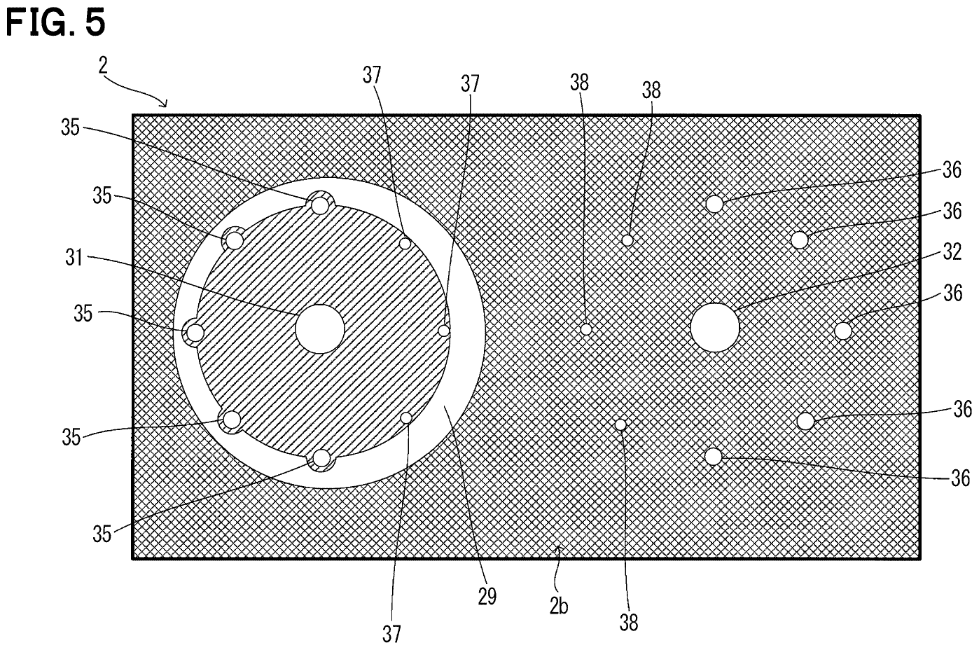

As shown in FIG. 2, FIG. 3, FIG. 4, and FIG. 5, a plurality of positive electrode through vias 35 are formed around the positive electrode terminal through hole 31, and a plurality of negative electrode through vias 36 are formed around the negative electrode terminal through hole 32.

The positive electrode through vias 35 and the negative electrode through vias 36 are formed so as to penetrate through the dielectric layers 21 to 29. A conductor 35a is formed over the entire inner circumferential surface of each of the positive electrode through vias 35. In addition, a conductor 36a is formed over the entire inner circumferential surface of each of the negative electrode through vias 36. Hereinafter, the conductor 35a and the conductor 36a will be referred to as a positive electrode through via conductor 35a and a negative electrode through via conductor 36a, respectively.

As shown in FIG. 3, the positive electrode through vias 35 and the negative electrode through vias 36 are arranged outside an inner layer via arrangement region R1, which will be described later. In FIG. 3, a region R2 indicated by a dashed circle is a region immediately below the capacitor 100.

The inner layer via arrangement region R1 is a region located just under the capacitor 100 and between a first straight line L1 and a second straight line L2, which will be described later. The first straight line L1 and the second straight line L2 are arranged parallel to each other and separated by a distance TD between the positive electrode terminal through hole 31 and the negative electrode terminal through hole 32 (hereinafter referred to as a through hole distance TD), and are two straight lines that intersect perpendicularly with a through hole connecting straight line L3 that connects a center C1 of the positive electrode terminal through hole 31 and a center C2 of the negative electrode terminal through hole 32, and are arranged between the positive electrode terminal through hole 31 and the negative electrode terminal through hole 32.

As shown in FIG. 2 and FIG. 3, the conductive pattern layer 11 includes first positive electrode connection patterns 111 that connect the positive electrode terminal through hole conductor 31a and the positive electrode through via conductors 35a, and first negative electrode connection patterns 112 that connect the negative electrode terminal through hole conductor 32a and the negative electrode through via conductors 36a.

As shown in FIG. 2 and FIG. 4, a plurality of positive electrode inner layer vias 37 are formed around the positive electrode terminal through hole 31, and a plurality of negative electrode inner layer vias 38 are formed around the negative electrode terminal through hole 32. The positive electrode inner layer vias 37 and the negative electrode inner layer vias 38 are arranged in the inner layer via arrangement region R1.

The positive electrode inner layer vias 37 and the negative electrode inner layer vias 38 are formed so as to penetrate through the dielectric layers 22 to 29. A conductor 37a is formed over the entire inner circumferential surface of each of the positive electrode inner layer vias 37. In addition, a conductor 38a is formed over the entire inner circumferential surface of each of the negative electrode inner layer vias 38. Hereinafter, the conductor 37a and the conductor 38a will be referred to as a positive electrode inner layer via conductor 37a and a negative electrode inner layer via conductor 38a, respectively.

The conductive pattern layer 12 includes first positive electrode connection patterns 121 that connect the positive electrode terminal through hole conductor 31a and the positive electrode through via conductors 35a, and first negative electrode connection pattern 122 that connect the negative electrode terminal through hole conductor 32a and the negative electrode through via conductors 36a.

The conductive pattern layer 12 further includes second positive electrode connection patterns 123 that connect the positive electrode terminal through hole conductor 31a and the positive electrode inner layer via conductors 37a, and second negative electrode connection patterns 124 that connect the negative electrode terminal through hole conductor 32a and the negative electrode inner layer via conductors 38a.

As shown in FIG. 2, the conductive pattern layers 13, 14, 15, 16, 17, 18, 19, 20 respectively include first positive electrode connection patterns 131, 141, 151, 161, 171, 181, 191, 201 that connect the positive electrode terminal through hole conductor 31a and the positive electrode through via conductors 35a, and first negative electrode connection patterns 132, 142, 152, 162, 172, 182, 192, 202 that connect the negative electrode terminal through hole conductor 32a and the negative electrode through via conductors 36a.

In addition, the conductive pattern layers 13, 14, 15, 16, 17, 18, 19, 20 respectively include second positive electrode connection patterns 133, 143, 153, 163, 173, 183, 193, 203 that connect the positive electrode terminal through hole conductor 31a and the positive electrode inner layer via conductors 37a, and second negative electrode connection patterns 134, 144, 154, 164, 174, 184, 194, 204 that connect the negative electrode terminal through hole conductor 32a and the negative electrode inner layer via conductors 38a.

The printed circuit board 2 configured in this manner includes the first dielectric layer 21 to the ninth dielectric layer 29, the first conductive pattern layer 11 to the tenth conductive pattern layer 20, the positive electrode terminal through hole 31, the negative electrode terminal through hole 32, the positive electrode inner layer vias 37, and the negative electrode inner layer vias 38.

The conductive pattern layers 11 to 20 are laminated alternately with the dielectric layers 21 to 29. The positive electrode terminal through hole 31 penetrates through the first dielectric layer 21 to the ninth dielectric layer 29, and has the inner circumferential surface on which the positive electrode terminal through hole conductor 31a is disposed. The positive electrode terminal 101 of the capacitor 100 is inserted into the positive electrode terminal through hole 31.

The negative electrode terminal through hole 32 penetrates through the first dielectric layer 21 to the ninth dielectric layer 29, and has the inner circumferential surface on which the negative electrode terminal through hole conductor 32a is disposed. The negative electrode terminal 102 of the capacitor 100 is inserted into the negative electrode terminal through hole 32.

Each of the positive electrode inner layer vias 37 penetrates through each of the second dielectric layer 22 to the ninth dielectric layer 29, and has the inner circumferential surface on which the positive electrode inner layer via conductor 37a is disposed. At least a portion of the positive electrode inner layer vias 37 is included within the inner layer via arrangement region R1. The inner layer via arrangement region R1 is a region that is located just under the capacitor 100 when the capacitor 100 is mounted above the first conductive pattern layer 11 by inserting the positive electrode terminal 101 and the negative electrode terminal 102 into the positive electrode terminal through hole 31 and the negative electrode terminal through hole 32, respectively, and is sandwiched between the first straight line L1 and the second straight line L2.

Each of the negative electrode inner layer vias 38 penetrates through each of the second dielectric layer 22 to the ninth dielectric layer 29, and has the inner circumferential surface on which the negative electrode inner layer via conductor 38a is disposed. At least a portion of the negative electrode inner layer vias 38 is included within the inner layer via arrangement region R1.

At least one of the second conductive pattern layer 12 to the tenth conductive pattern layer 20 connects the positive electrode terminal through hole 31 and the positive electrode inner layer vias 37, and connects the negative electrode terminal through hole 32 and the negative electrode inner layer vias 38.

The printed circuit board 2 described above includes the positive electrode inner layer vias 37 connected to the positive electrode terminal through hole 31 and the negative electrode inner layer via s38 connected to the negative electrode terminal through hole 32, thereby increasing the number of paths for conducting heat between the first conductive pattern layer 11 and the tenth conductive pattern layer 20, and making it easier to conduct heat between the first conductive pattern layer 11 and the tenth conductive pattern layer 20. This makes it easier for heat generated during soldering to be conducted between portions adjacent to the first conductive pattern layer 11 and portions adjacent to the tenth conductive pattern layer 20 in the positive electrode terminal through hole 31 and the negative electrode terminal through hole 32. Therefore, the printed circuit board 2 can restrict deterioration of the solderability when the positive electrode terminal 101 and the negative electrode terminal 102 of the capacitor 100 are soldered into the positive electrode terminal through hole 31 and the negative electrode terminal through hole 32, respectively.

Furthermore, in the printed circuit board 2, the positive electrode inner layer vias 37 and the negative electrode inner layer via s38 arranged in the inner layer via arrangement region R1 are not exposed on the mounting surface 2a of the printed circuit board 2 on which the capacitor 100 is mounted. Accordingly, the printed circuit board 2 can restrict the occurrence of a situation in which the capacitor 100 shorts out between the positive electrode terminal through hole 31 and the negative electrode terminal through hole 32 when electrolyte leaks from the capacitor 100 mounted on the printed circuit board 2.

At least a portion of the positive electrode inner layer vias 37 and at least a portion of the negative electrode inner layer vias 38 may be included within a central area CA shown in FIG. 4. The central region CA is a region of the inner layer via arrangement region R1 that is sandwiched between the positive electrode terminal through hole 31 and the negative electrode terminal through hole 32. The printed circuit board 2 having the above-described configuration is highly effective in restricting short circuits because the printed circuit board 2 can restrict the occurrence of short circuits in the central region CA, where there is a high possibility that the capacitor 100 will short between the positive electrode terminal through hole 31 and the negative electrode terminal through hole 32 when electrolyte leaks from the capacitor 100 mounted on the printed circuit board 2.

Accordingly, the reliability of the printed circuit board 2 can be improved. In the present embodiment, the positive electrode terminal through hole 31 corresponds to a first through hole, the negative electrode terminal through hole 32 corresponds to a second through hole, the positive electrode terminal through hole conductor 31a corresponds to a first through hole conductor, and the negative electrode terminal through hole conductor 32a corresponds to a second through hole conductor. The positive electrode inner layer vias 37 and the negative electrode inner layer vias 38 correspond to inner layer vias, and the positive electrode inner layer via conductors 37a and the negative electrode inner layer via conductors 38a correspond to inner layer via conductors.

### Second Embodiment

Hereinafter, a second embodiment according to the present disclosure will be described with reference to the drawings. In the second embodiment, portions different from those of the first embodiment will be described. Common configurations are denoted by the same reference numerals.

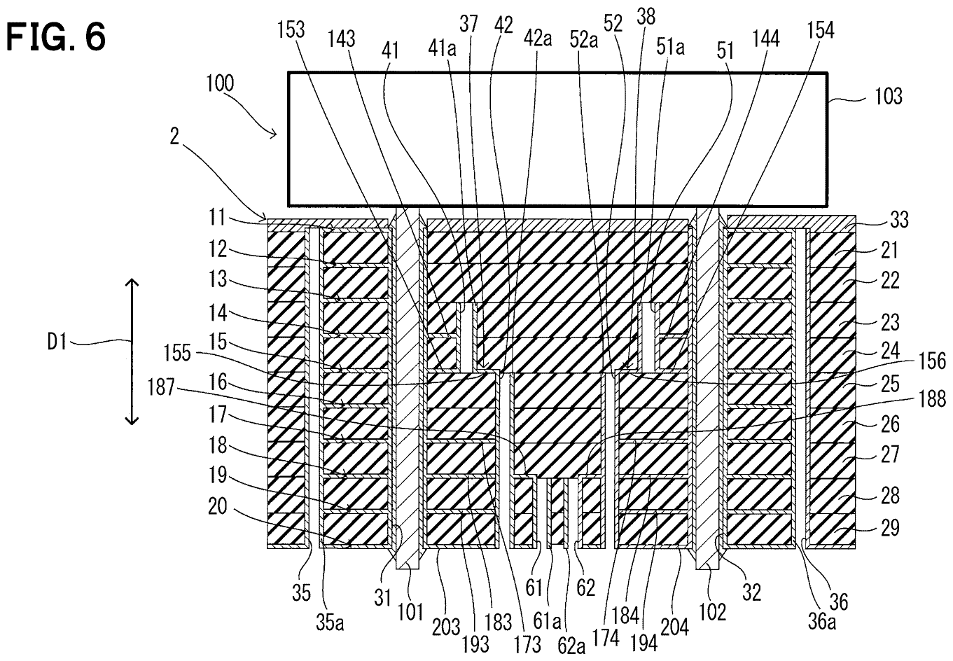

The electronic control device 1 of the second embodiment differs from the first embodiment in that the shapes of the positive electrode inner layer vias 37 and the negative electrode inner layer vias 38 are changed and in that additional inner layer vias 61 and 62 are added. As shown in FIG. 6, each of the positive electrode inner layer vias 37 includes split vias 41 and 42 and a third positive electrode connection pattern 155.

The split via 41 penetrates through the dielectric layers 23 and 24. A conductor 41a is formed over the entire inner circumferential surface of the split via 41. The split via 42 penetrates through the dielectric layers 25 to 29. A conductor 42a is formed over the entire inner circumferential surface of the split via 42. Hereinafter, the conductors 41a and 42a will be referred to as split via conductors 41a and 42a, respectively.

The split via 41 is connected to the positive electrode terminal through hole 31 by the second positive electrode connection patterns 143 and 153. The split via 42 is connected to the positive electrode terminal through hole 31 by the second positive electrode connection patterns 173, 183, 193, and 203.

The conductive pattern layer 15 includes the third positive electrode connection pattern 155 that connects the split via conductor 41a and the split via conductor 42a. Each of the negative electrode inner layer vias 38 includes split vias 51 and 52 and a third negative electrode connection pattern 156.

The split via 51 penetrates through the dielectric layers 23 and 24. A conductor 51a is formed over the entire inner circumferential surface of the split via 51. The split via 52 penetrates through the dielectric layers 25 to 29. A conductor 52a is formed over the entire inner circumferential surface of the split via 52. Hereinafter, the conductors 51a and 52a will be referred to as split via conductors 51a and 52a, respectively.

The split via 51 is connected to the negative electrode terminal through hole 32 by the second negative electrode connection patterns 144 and 154. The split via 52 is connected to the negative electrode terminal through hole 32 by the second negative electrode connection patterns 174, 184, 194, and 204.

The conductive pattern layer 15 includes the third negative electrode connection pattern 156 that connects the split via conductor 51a and the split via conductor 52a. The additional inner layer vias 61, 62 are formed in the inner layer via arrangement region R1 so as to penetrate through the dielectric layers 28 and 29. Conductors 61a, 62a are formed over the entire inner circumferential surfaces of the additional inner layer vias 61, 62, respectively. Hereinafter, the conductors 61a and 62a are referred to as additional inner layer via conductors 61a and 62a, respectively.

The conductive pattern layer 18 includes a fourth positive electrode connection pattern 187 connecting the split via conductor 42a and the additional inner layer via conductor 61a, and a fourth negative electrode connection pattern 188 connecting the split via conductor 52a and the additional inner layer via conductor 62a.

In the printed circuit board 2 having the above-described configuration, each of the positive electrode inner layer vias 37 includes the split vias 41 and 42 that penetrate at least one dielectric layer. The split via 41 penetrates through the dielectric layers 23 and 24. The split via 42 penetrates through the dielectric layers 25 to 29. Each of the negative electrode inner layer via 38 includes the split vias 51 and 52 that penetrate through at least one dielectric layer. The split via 51 penetrates through the dielectric layers 23 and 24. The split via 52 passes through the dielectric layers 25 to 29. Specifically, each of the positive electrode inner layer vias 37 is formed in a non-linear shape along the laminating direction D1 by connecting the split vias 41 and 42 with the third positive electrode connection pattern 155. Moreover, each of the negative electrode inner layer vias 38 is formed in a non-linear shape along the laminating direction D1 by connecting the split vias 51 and 52 with the third negative electrode connection pattern 156.

In the printed circuit board 2 having the above-described configuration, the arrangement of the split vias 41, 51 and the split vias 42, 52 can be changed to change the shapes of the positive electrode inner layer vias 37 and the negative electrode inner layer vias 38 according to the wiring pattern within the printed circuit board 2, thereby ensuring freedom of circuit design.

In addition, the printed circuit board 2 further includes the additional inner layer vias 61 and 62 that penetrate through each of the third dielectric layer 23 to the ninth dielectric layer 29 in the inner layer via arrangement region R1 and have the additional inner layer via conductors 61a, 62a formed on their inner surfaces. The additional inner layer via 61 and the additional inner layer via 62 are connected to the positive electrode inner layer via 37 and the negative electrode inner layer via 38 by the fourth positive electrode connection pattern 187 and the fourth negative electrode connection pattern 188, respectively.

The printed circuit board 2 having the above-described configuration includes the additional inner layer vias 61, 62, thereby increasing the number of paths for conducting heat between the first conductive pattern layer 11 and the tenth conductive pattern layer 20, and making it easier to conduct heat between the first conductive pattern layer 11 and the tenth conductive pattern layer 20. Therefore, the printed circuit board 2 can further restrict deterioration of the solderability when the positive electrode terminal 101 and the negative electrode terminal 102 of the capacitor 100 are soldered into the positive electrode terminal through hole 31 and the negative electrode terminal through hole 32, respectively.

Although embodiments of the present disclosure have been described above, the present disclosure is not limited to the above-described embodiments, and various modifications can be made.

### First Modification

In the above-described embodiments, the first conductive pattern layer 11 to the tenth conductive pattern layer 20 are provided, but the number of conductive pattern layers may be three or greater. In other words, the printed circuit board 2 may include a first conductive pattern layer 11 to an Nth conductive pattern layer, where N is an integer that is greater than or equal to three.

### Second Modification

In the above-described embodiments, the positive electrode inner layer vias 37 and the negative electrode inner layer vias 38 penetrate through the dielectric layers 22 to 29. However, the positive electrode inner layer vias 37 and the negative electrode inner layer vias 38 may penetrate through the dielectric layers from any one of the dielectric layers 23 to 29 to the dielectric layer 29. In other words, the inner layer vias 37 and 38 may penetrate through each dielectric layer from an Mth dielectric layer to the (N-1)th dielectric layer in the plurality of dielectric layers, where M is an integer that is greater than or equal to two and less than or equal to (N-1). For example, the positive electrode inner layer vias 37 and the negative electrode inner layer vias 38 may penetrate through the dielectric layers 25 to 29.

### Third Modification

In the above-described embodiment, the additional inner layer vias 61 and 62 penetrate through the dielectric layers 28 to 29. However, the additional inner layer vias 61 and 62 may penetrate through the dielectric layers from any one of the dielectric layers 22 to 29 to the dielectric layer 29. In other words, the additional inner layer vias 61 and 62 may penetrate through each dielectric layer from an Lth dielectric layer to the (N-1)th dielectric layer in the plurality of dielectric layers, where L is an integer that is greater than equal to two and less than or equal to (N-1). For example, the additional inner layer vias 61 and 62 may penetrate through the dielectric layers 22 to 29.

### Fourth Modification

In the above-described embodiments, the positive electrode inner layer vias 37 and the negative electrode inner layer vias 38 are entirely disposed within the inner layer via arrangement region R1. However, at least portions of the positive electrode inner layer vias 37 and the negative electrode inner layer vias 38 may be disposed within the inner layer via arrangement region R1.

A plurality of functions belonging to one configuration element in the above-described embodiments may be implemented by a plurality of configuration elements, or one function belonging to one configuration element may be implemented by a plurality of configuration elements. A plurality of functions belonging to a plurality of configuration elements may be implemented by one configuration element, or one function implemented by a plurality of configuration elements may be implemented by one configuration element. A part of the configuration of the above-described embodiments may be omitted. Further, at least part of the configuration of the above-described embodiments may be added to or replaced with the configuration of another embodiment described above.

What is claimed is:

1. A printed circuit board comprising:
a plurality of dielectric layers from a first dielectric layer to an (N-1)th dielectric layer, where N is an integer that is greater than or equal to three;
a plurality of conductive pattern layers from a first conductive pattern layer to an Nth conductive pattern layer alternately laminated with the plurality of dielectric layers in such a manner that the first conductive pattern layer is disposed above the first dielectric layer and the (N-1)th dielectric layer is disposed above the Nth conductive pattern layer;
a first through hole penetrating through the plurality of dielectric layers from the first dielectric layer to the (N-1)th dielectric layer, having an inner circumferential surface on which a first through hole conductor is disposed, and into which a positive electrode terminal of a capacitor is to be inserted in a state where the capacitor is mounted above the first conductive pattern layer;
a second through hole penetrating through the plurality of dielectric layers from the first dielectric layer to the (N-1)th dielectric layer, having an inner circumferential surface on which a second through hole conductor is disposed, and into which a negative electrode terminal of the capacitor is to be inserted in the state where the capacitor is mounted above the first conductive pattern layer; and
an inner layer via penetrating through each dielectric layer from an Mth dielectric layer to the (N-1)th dielectric layer in the plurality of dielectric layers, where M is an integer that is greater than or equal to two and less than or equal to (N-1), and having an inner circumferential surface on which an inner layer via conductor is disposed, wherein
at least a portion of the inner layer via is disposed in an inner via arrangement region,
the inner via arrangement region is a region that is located just under the capacitor in the state where the capacitor is mounted above the first conductive pattern layer and the positive electrode terminal and the negative electrode terminal of the capacitor are inserted into the first through hole and the second through hole, respectively, and the inner via arrangement region is sandwiched between a first straight line and a second straight line,
the first straight line and the second straight line are arranged parallel to each other and separated from each other by a through hole distance that is a distance between the first through hole and the second through hole, the first straight line and the second straight line intersect perpendicularly a through hole connecting straight line that connects a center of the first through hole and a center of the second through hole, and the first straight line and the second straight line are arranged between the first through hole and the second through hole, and
at least one of the first through hole and the second through hole is connected to the inner layer via with at least one conductive pattern layer that is selected from an Mth conductive pattern layer to the Nth conductive pattern layer in the plurality of conductive pattern layers.

2. The printed circuit board according to claim 1, wherein
the inner layer via includes a plurality of split vias each penetrating at least one dielectric layer in the plurality of dielectric layers.

3. The printed circuit board according to claim 2, wherein
the inner layer via is formed in a non-linear shape along a laminating direction in which the plurality of dielectric layers are laminated, by connecting the plurality of split vias with at least one conductive pattern layer in the plurality of conductive pattern layers.

4. The printed circuit board according to claim 1, further comprising
an additional inner layer via disposed within the inner via arrangement region, penetrating through each dielectric layer from an Lth dielectric layer to the (N-1)th dielectric layer in the plurality of dielectric layers, where L is an integer that is greater than equal to two and less than or equal to (N-1), and having an inner circumferential surface on which an additional inner layer via conductor is disposed, wherein
the additional inner layer via is connected to the inner layer via with at least one conductive pattern layer in the plurality of conductive pattern layers.

5. The printed circuit board according to claim 1, wherein
at least a portion of the inner layer via is disposed in a central region of the inner layer via arrangement region that is sandwiched between the first through hole and the second through hole.

6. An electronic control device comprising a capacitor and a printed circuit board on which the capacitor is mounted, wherein the printed circuit board includes:
a plurality of dielectric layers from a first dielectric layer to an (N-1)th dielectric layer, where N is an integer that is greater than or equal to three;
a plurality of conductive pattern layers from a first conductive pattern layer to an Nth conductive pattern layer alternately laminated with the plurality of dielectric layers in such a manner that the first conductive pattern layer is disposed above the first dielectric layer, and the (N-1)th dielectric layer is disposed above the Nth conductive pattern layer;
a first through hole penetrating through the plurality of dielectric layers from the first dielectric layer to the (N-1)th dielectric layer, having an inner circumferential surface on which a first through hole conductor is disposed, and into which a positive electrode terminal of the capacitor is inserted in a state where the capacitor is mounted above the first conductive pattern layer;
a second through hole penetrating through the plurality of dielectric layers from the first dielectric layer to the (N-1)th dielectric layer, having an inner circumferential surface on which a second through hole conductor is disposed, and into which a negative electrode terminal of the capacitor is inserted in the state where the capacitor is mounted above the first conductive pattern layer; and
an inner layer via penetrating through each dielectric layer from an Mth dielectric layer to the (N-1)th dielectric layer in the plurality of dielectric layers, where M is an integer that is greater than or equal to two and less than or equal to (N-1), and having an inner circumferential surface on which an inner layer via conductor is disposed, wherein
at least a portion of the inner layer via is disposed in an inner via arrangement region,
the inner via arrangement region is a region that is located just under the capacitor in the state where the capacitor is mounted above the first conductive pattern layer and the positive electrode terminal and the negative electrode terminal of the capacitor are inserted into the first through hole and the second through hole, respectively, and the inner via arrangement region is sandwiched between a first straight line and a second straight line,
the first straight line and the second straight line are arranged parallel to each other and separated from each other by a through hole distance that is a distance between the first through hole and the second through hole, the first straight line and the second straight line intersect perpendicularly a through hole connecting straight line that connects a center of the first through hole and a center of the second through hole, and the first straight line and the second straight line are arranged between the first through hole and the second through hole, and
at least one of the first through hole and the second through hole is connected to the inner layer via with at least one conductive pattern layer that is selected from an Mth conductive pattern layer to the Nth conductive pattern layer in the plurality of conductive pattern layers.

7. The electronic control device according to claim 6, wherein
the inner layer via includes a plurality of split vias each penetrating at least one dielectric layer in the plurality of dielectric layers.

8. The electronic control device according to claim 7, wherein
the inner layer via is formed in a non-linear shape along a laminating direction in which the plurality of dielectric layers are laminated, by connecting the plurality of split vias with at least one conductive pattern layer in the plurality of conductive pattern layers.

9. The electronic control device according to claim 6, further comprising
an additional inner layer via disposed within the inner via arrangement region, penetrating through each dielectric layer from an Lth dielectric layer to the (N-1)th dielectric layer in the plurality of dielectric layers, where L is an integer that is greater than or equal to two and less than or equal to (N-1), and having an inner circumferential surface on which an additional inner layer via conductor is disposed, wherein
the additional inner layer via is connected to the inner layer via with at least one conductive pattern layer in the plurality of conductive pattern layers.

10. The electronic control device according to claim 6, wherein
at least a portion of the inner layer via is disposed in a central region of the inner layer via arrangement region that is sandwiched between the first through hole and the second through hole.
